(19) United States
(12) Patent Application Publication
(10) Pub. No.: US 2015/0042412 A1
(43) Pub. Date: Feb. 12, 2015

(54) DIRECTIONAL COUPLER CIRCUIT TECHNIQUES

(71) Applicant: QUALCOMM Incorporated, San Diego, CA (US)

(72) Inventors: James Francis Imbornone, Boxborough, MA (US); Yanjie Sun, Boxborough, MA (US); Zhenying Luo, Boxborough, MA (US); Zhenqi Chen, Acton, MA (US); Calogero D. Presti, San Diego, CA (US); Xinwei Wang, Dunstable, MA (US); Dong Zhang, Boxborough, MA (US)

(73) Assignee: QUALCOMM Incorporated, San Diego, CA (US)

(21) Appl. No.: 13/961,861

(22) Filed: Aug. 7, 2013

(51) Int. Cl. H03H 7/48; H01P 5/18

(52) U.S. Cl. CPC H03H 7/463
USPC 333/112

(57) ABSTRACT

Techniques for efficiently integrating directional coupler circuitry with other circuit elements of an RF front end. In an aspect, one or more inductors of an RF front end filter is incorporated into a first inductor of the directional coupler, and a capacitor is further coupled in parallel with the first inductor. In another aspect, circuitry associated with matching components of the RF front end may further be incorporated into the directional coupler design. Further techniques are provided for coupling directivity tuning elements to a second inductor of the directional coupler to improve the linearity of the coupler over other tuning techniques.

### BACKGROUND

1. Field

The disclosure relates to techniques for designing circuitry for radio applications.

2. Background

Modern radios typically employ one or more antennas coupled to and from radio transceiver circuitry (e.g., a power amplifier on the transmit side, or a low-noise amplifier on the receive side) to process radio-frequency signals. Certain RF circuitry may be coupled to the antenna to perform various functions, e.g., switching, impedance matching, filtering, coupling, etc., for both transmit and receive sides. Prior art techniques for implementing such RF circuitry include providing, e.g., an analog switch network, a directional coupler, one or more filters, and matching components, which may be cascaded in series.

A series cascade architecture advantageously affords multiple degrees of freedom in designing the aforementioned RF circuitry, as well as relative isolation between the circuit functions. However, such an architecture may undesirably increase the insertion loss of the RF circuitry. Such insertion loss may be a key contributor to the overall transmitter efficiency and receiver noise figure of the radio.

Accordingly, it would be desirable to provide efficient and low-cost techniques for designing RF front end circuitry to reduce their insertion loss, while preserving or even enhancing their performance specifications.

### BRIEF DESCRIPTION OF THE DRAWINGS

FIG. 1 illustrates a block diagram of a design of a prior art wireless communication device in which the techniques of the present disclosure may be implemented.

FIG. 2 illustrates an implementation of a portion of a prior art transceiver accommodating multiple frequency bands and modes.

FIG. 3 illustrates an exemplary embodiment of the present disclosure.

FIGS. 4A, 4B, 4C, and 4D illustrate alternative exemplary embodiments of the present invention, showing integrated coupling, filtering, and matching functionality.

FIG. 5 illustrates an alternative prior art implementation of a portion of RF front-end circuitry according to the present disclosure.

FIGS. 6 and 6A illustrate alternative exemplary embodiments of RF front-end circuitry according to the present disclosure, showing coupler and impedance matching/filter components of FIG. 5 integrated into a common structure.

FIGS. 7 and 7A illustrate exemplary embodiments incorporating coupler directivity tuning techniques according to the present disclosure.

FIG. 8 illustrates an alternative exemplary embodiment of directivity tuning techniques of the present disclosure.

FIG. 9 illustrates an exemplary embodiment of a method according to the present disclosure.

FIG. 10 illustrates an alternative exemplary embodiment illustrating certain techniques of the present disclosure as applied to an analog switching module.

### DETAILED DESCRIPTION

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings herein one skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

The detailed description set forth below in connection with the appended drawings is intended as a description of exemplary aspects of the invention and is not intended to represent the only exemplary aspects in which the invention can be practiced. The term “exemplary” used throughout this description means “serving as an example, instance, or illustration,” and should not necessarily be construed as preferred or advantageous over other exemplary aspects. The detailed description includes specific details for the purpose of providing a thorough understanding of the exemplary aspects of the invention. It will be apparent to those skilled in the art that the exemplary aspects of the invention may be practiced without these specific details. In some instances, well-known structures and devices are shown in block diagram form in order to avoid obscuring the novelty of the exemplary aspects presented herein. In this specification and in the claims, the terms “module” and “block” may be used interchangeably to denote an entity configured to perform the operations described.

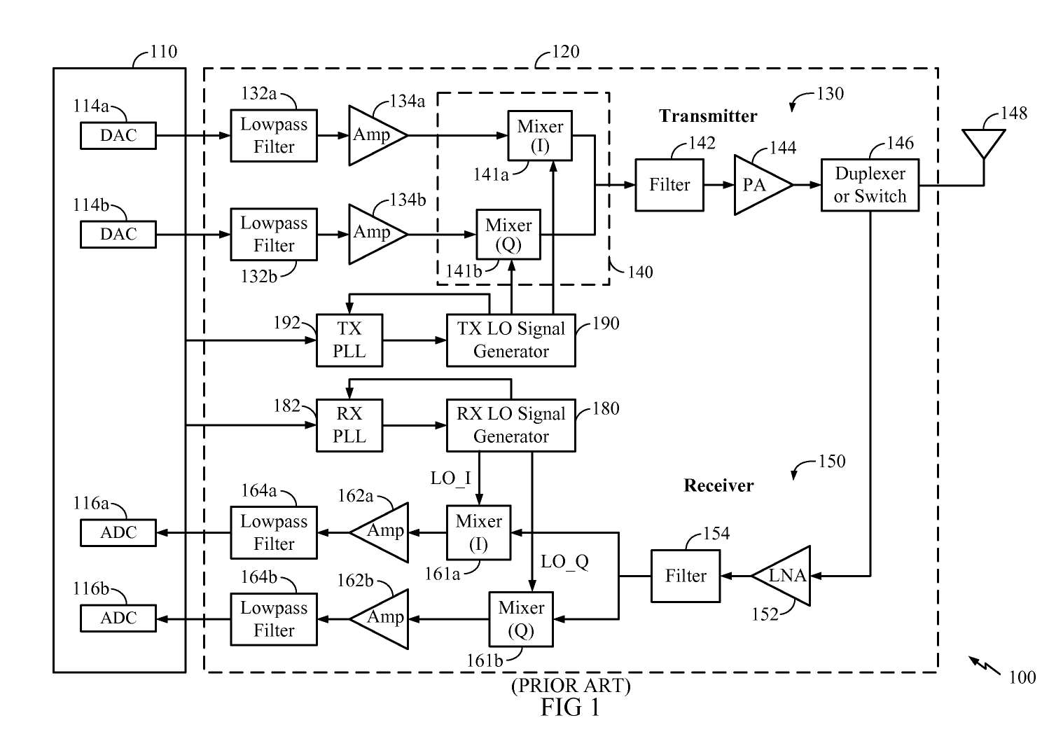

FIG. 1 illustrates a block diagram of a design of a prior art wireless communication device 100 in which the techniques of the present disclosure may be implemented. FIG. 1 shows an example transceiver design. In general, the conditioning of the signals in a transmitter and a receiver may be performed by one or more stages of amplifier, filter, upconverter, downconverter, etc. These circuit blocks may be arranged differently from the configuration shown in FIG. 1. Furthermore, other circuit blocks not shown in FIG. 1 may also be used to condition the signals in the transmitter and receiver. Unless otherwise noted, any signal in FIG. 1, or any other figure in the drawings, may be either single-ended or differential. Some circuit blocks in FIG. 1 may also be omitted.

In the design shown in FIG. 1, wireless device 100 includes a transceiver 120 and a data processor 110. The data processor 110 may include a memory (not shown) to store data and program codes. Transceiver 120 includes a transmitter 130 and a receiver 150 that support bi-directional communication. In general, wireless device 100 may include any number of transmitters and/or receivers for any number of communication systems and frequency bands. All or a portion of transceiver 120 may be implemented on one or more analog integrated circuits (ICs), RF ICs (RFICs), mixed-signal ICs, etc.

A transmitter or a receiver may be implemented with a super-heterodyne architecture or a direct-conversion architecture. In the super-heterodyne architecture, a signal is frequency-converted between radio frequency (RF) and baseband in multiple stages, e.g., from RF to an intermediate frequency (IF) in one stage, and then from IF to baseband in another stage for a receiver. In the direct-conversion architecture, a signal is frequency converted between RF and baseband in one stage. The super-heterodyne and direct-conversion architectures may use different circuit blocks and/or have different requirements. In the design shown in FIG. 1, transmitter 130 and receiver 150 are implemented with the direct-conversion architecture.

In the transmit path, data processor 110 processes data to be transmitted and provides I and Q analog output signals to transmitter 130. In the exemplary embodiment shown, the data processor 110 includes digital-to-analog-converters (DAC's) 114a and 114b for converting digital signals generated by the data processor 110 into the I and Q analog output signals, e.g., I and Q output currents, for further processing.

Within transmitter 130, lowpass filters 132a and 132b filter the I and Q analog output signals, respectively, to remove undesired images caused by the prior digital-to-analog conversion. Amplifiers (Amp) 134a and 134b amplify the signals from lowpass filters 132a and 132b, respectively, and provide I and Q baseband signals. An upconverter 140 upconverts the I and Q baseband signals with I and Q transmit (TX) local oscillator (LO) signals from a TX LO signal generator 190 and provides an upconverted signal. A filter 142 filters the upconverted signal to remove undesired images caused by the frequency upconversion as well as noise in a receive frequency band. A power amplifier (PA) 144 amplifies the signal from filter 142 to obtain the desired output power level and provides a transmit RF signal. The transmit RF signal is routed through a duplexer or switch 146 and transmitted via an antenna 148.

In the receive path, antenna 148 receives signals transmitted by base stations and provides a received RF signal, which is routed through duplexer or switch 146 and provided to a low noise amplifier (LNA) 152. The duplexer 146 is designed to operate with a specific RX-to-TX duplexer frequency separation, such that RX signals are isolated from TX signals. The received RF signal is amplified by LNA 152 and filtered by a filter 154 to obtain a desired RF input signal. Downconversion mixers 161a and 161b mix the output of filter 154 with I and Q receive (RX) LO signals (i.e., LO_I and LO_Q) from an RX LO signal generator 180 to generate I and Q baseband signals. The I and Q baseband signals are amplified by amplifiers 162a and 162b and further filtered by lowpass filters 164a and 164b to obtain I and Q analog input signals, which are provided to data processor 110. In the exemplary embodiment shown, the data processor 110 includes analog-to-digital-converters (ADC's) 116a and 116b for converting the analog input signals into digital signals to be further processed by the data processor 110.

In FIG. 1, TX LO signal generator 190 generates the I and Q TX LO signals used for frequency upconversion, while RX LO signal generator 180 generates the I and Q RX LO signals used for frequency downconversion. Each LO signal is a periodic signal with a particular fundamental frequency. A PLL 192 receives timing information from data processor 110 and generates a control signal used to adjust the frequency and/or phase of the TX LO signals from LO signal generator 190. Similarly, a PLL 182 receives timing information from data processor 110 and generates a control signal used to adjust the frequency and/or phase of the RX LO signals from LO signal generator 180.

In certain implementations (not shown in FIG. 1), a balun may be provided between the output of the LNA 152 and the mixers 161a, 161b of the receiver 150. The balun may convert a single-ended signal to a differential signal, and may include, e.g., a transformer that mutually couples a signal from a primary winding to a secondary winding. Furthermore, in certain alternative implementations not shown, a plurality of LNA's 152 may be provided, wherein each LNA is optimized to process an input RF signal in a particular frequency band.

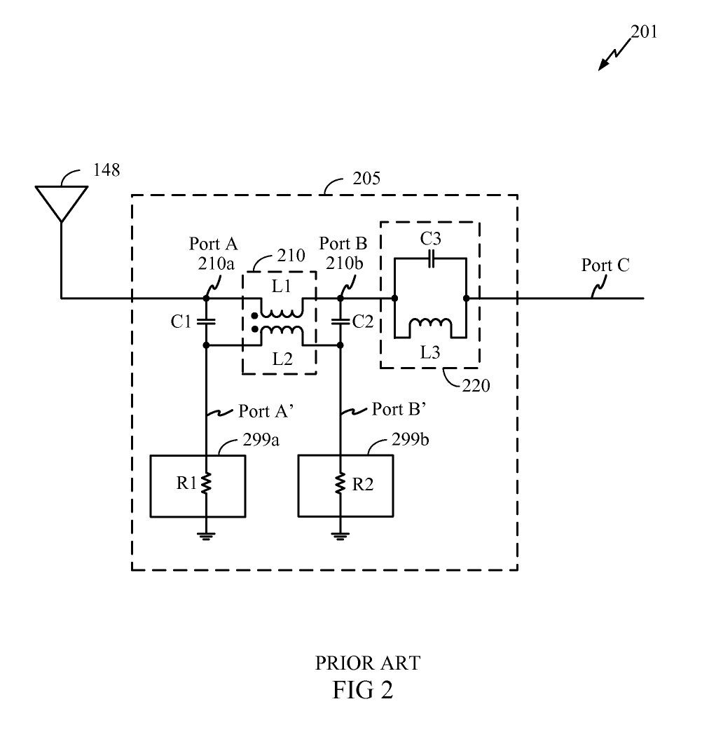

FIG. 2 illustrates an implementation of a portion 201 of a prior art transceiver. Note FIG. 2 is shown for illustrative purposes only, and is not meant to limit the scope of the present disclosure.

In FIG. 2, a portion 201 of a radio includes antenna 148 coupled to an associated RF circuit block 205. Block 205 passes signal power at Port A through Port B to Port C via a directional coupler 210 (also denoted herein as a “coupler”) and an L-C filter 220. In certain implementations, the power at Port A may be that of the signal received by antenna 148, and/or the power at Port A may be that of the signal being transmitted by the antenna 148. The power at Port B′ may be related to, e.g., the output power of a transmitter 130 (not shown in FIG. 2), and/or the power at Port A′ may be related to that of an input signal provided to a receiver 150 (not shown in FIG. 2).

In block 205, coupler 210 includes mutually coupled inductors L1 and L2. In certain implementations, inductors L1, L2 may correspond to, e.g., the primary and secondary windings of a transformer. Capacitances C1 and C2 further couple the respective terminals of L1 and L2 to each other. C1 is further coupled by a resistance R1 to ground, and C2 is further coupled by a resistance R2 to ground. Note in certain implementations, R1 and R2 may correspond to, e.g., the input impedances of further circuitry (not shown) connected to Ports A′ and B′, respectively, of coupler 210.

Note a main signal path may be defined herein as being between Ports A and B (also labeled terminals 210a and 210b, respectively) via inductor L1, while the auxiliary signal path may be defined as being between Ports A′ and B′ via inductor L2. It will be appreciated that the coupler 210 may mutually couple signals in the main signal path to the auxiliary signal path.

In FIG. 2, C1 and C2 (also denoted herein as “odd-mode” capacitors) may further be provided to improve the directivity of coupler 210. For example, C1 and C2 may be associated with parasitic capacitances present in the coupler 210, or they may be associated with explicitly provided capacitances. In the implementation shown, C1 and C2 are shown as being outside the coupler 210, although according to other conventions, C1 and C2 may also be considered as being provided within the coupler 210 itself.

During operation of the radio, L-C filter 220 performs a band-pass filtering function, e.g., to filter out jammer signals that are received via antenna 148 (e.g., jammer signals corresponding to transmissions from a wireless local area network, or Wi-Fi). It will be appreciated that directional couplers such as coupler 210 are known in the art, and are typically used to detect and distinguish between incident and reflected waveforms traveling between circuit components (e.g., between an antenna and a power amplifier or a receiver) of the main signal path.

During operation, the coupler 210 may mutually couple a directional component of a signal in the main signal path to the auxiliary signal path for further processing. For example, the coupler 210 may be designed to couple a signal in the main signal path having a first directionality, e.g., from Port B to Port A, to Port B′, which may in turn be coupled to a load 299b having port impedance represented by resistor R2. The coupler 210 may further be designed to couple a signal having a reverse directionality, e.g., from Port A to Port B, to Port A′, which may in turn be coupled to a load 299a having port impedance represented by resistor R1. RF processing applications utilizing directional coupler circuitry are known in the art. For example, the coupler may be utilized to perform automatic gain control (AGC) in a closed-loop manner for TX circuitry, etc., according to principles known in the art.

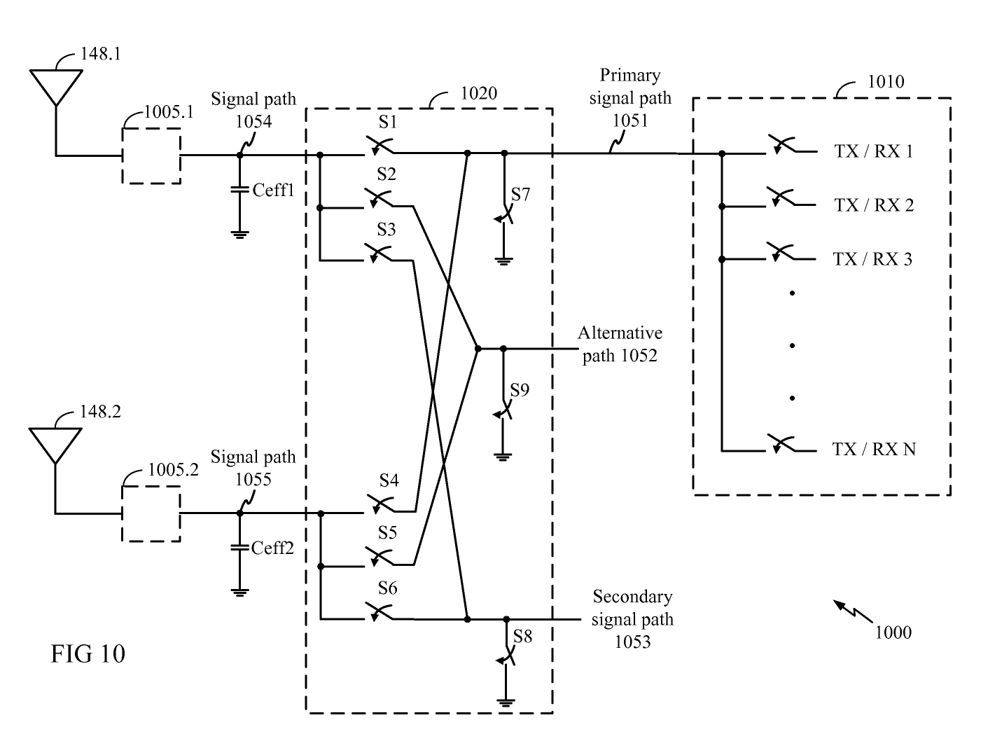

Note in certain implementations of a radio transceiver, further blocks not shown may be provided in conjunction with the circuitry in FIG. 2. For example, additional antennas (not shown) may be provided for spatial diversity, and such antennas may each be further coupled to circuitry having functionality analogous to that of circuitry 205. The outputs of such multiple antennas and circuitry may be selectively combined by switching techniques known in the art, e.g., cross-switching techniques as are known to combine TX and RX signals, and as further described hereinbelow with reference to FIG. 10. Furthermore, elements such as duplexers (not shown) may be coupled to circuitry 205 and/or corresponding circuitry of other antennas to share such antennas between TX and RX circuitry. Such alternative implementations may readily utilize the techniques described further hereinbelow for integrating certain elements of the RF front-end circuitry.

In the art of radio transceiver design, the loss of the main signal path (in both the TX and RX directions) is a key contributor to the overall transmitter efficiency and receiver noise figure. Accordingly, it is desired to minimize the insertion loss of elements in the RF signal path, e.g., such as may be attributed to circuitry 205. It would be desirable to provide techniques for designing front end components of the RF signal path to minimize insertion loss and maximize transceiver efficiency.

Per techniques of the present disclosure, the circuit elements forming the coupler, the filter, and/or the matching network may be provided in an integrated structure to minimize the losses in the RF signal path. In particular, certain individual components that are common to multiple blocks of the RF circuitry may be adapted to simultaneously serve multiple functions. For example, the same inductor used in the main signal path of the coupler may be re-used as a filter component, and/or re-used in a matching network, etc. Re-using components in this manner may advantageously lead to lower insertion losses than would otherwise be achieved using a conventional cascading of these components.

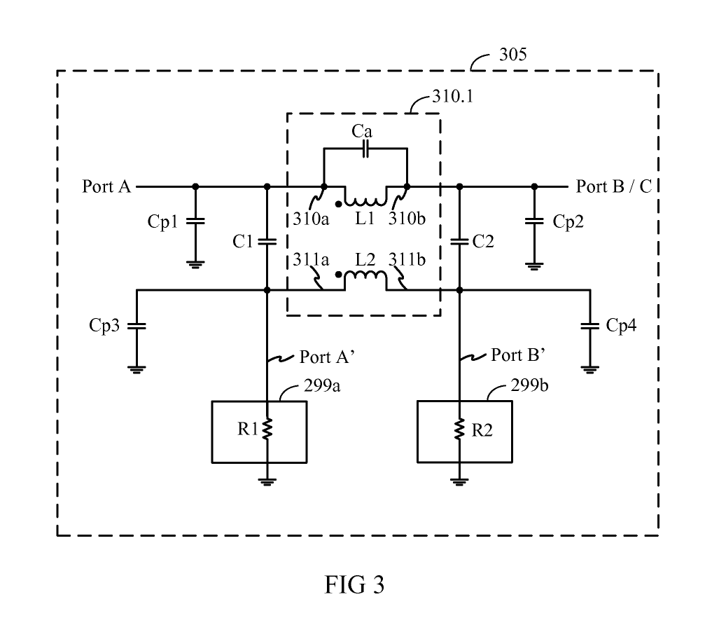

FIG. 3 illustrates an exemplary embodiment of the present disclosure. Note FIG. 3 is shown for illustrative purposes only, and is not meant to limit the scope of the present disclosure.

In FIG. 3, it will be understood that circuitry 305 shown therein, or parts thereof, may generally be substituted for block 205 shown in FIG. 2 in a general radio architecture. In particular, circuitry 305 includes Ports A, B, A′, and B′, similar to the circuitry 205 of FIG. 2. Note Port B of circuitry 305 is also indicated in FIG. 3 as Port B/C, as Ports B and C of circuitry 205 of FIG. 2 are effectively integrated into a single port Port B/C in circuitry 305, as further described hereinbelow.

Circuitry 305 includes an integrated block 310.1 coupled to various circuit elements. Integrated block 310.1 includes first and second mutually coupled inductors L1 and L2, respectively, which may implement, e.g., the primary and secondary windings of a transformer. Note the first inductor L1, including terminals 310a, 310b (also denoted herein as “end terminals”), is defined as being part of the main signal path, i.e., between Ports A and B. The second inductor L2, including terminals 311a, 311b, is mutually (magnetically) coupled to the first inductor L1. The second inductor L2 is part of the auxiliary signal path, and is not directly conductively coupled to the main signal path.

Further coupled in parallel with the terminals 310a, 310b of the first inductor L1 is a parallel capacitance Ca. In an exemplary embodiment, the values of Ca, L1, and L2 may be chosen such that block 310.1 provides integrated directional coupling and filtering capability. In particular, it will be appreciated that the parallel combination of L1 and Ca shown in block 310.1 will generally give rise to a notch transfer characteristic between Ports A and B. Furthermore, due to the mutual coupling between L1 and L2 described hereinabove, directional coupling will also be provided by block 310.1.

Note capacitances C1 and C2 couple the main and auxiliary signal paths to each other, and port resistances R1 and R2 further couple terminals 311a, 311b to ground, respectively. It will be appreciated that R1 and R2 may model the equivalent resistances of circuit blocks (not shown) coupled to terminals 311a, 311b, respectively. Accordingly, R1, R2 need not be explicitly provided resistor elements.

Note capacitances Cp1, Cp2, Cp3, and Cp4 (also denoted herein as “even-mode” capacitors) are further shown coupling Ports A, B, A′, and B′, respectively, to ground. In an exemplary embodiment, either Cp1 or Cp2 may be contributed by, e.g., parasitic capacitance associated with various circuitry, or one or more switch modules, not shown in FIG. 3.

By selecting appropriate values for L1 and Ca, and further accounting for the effects of, e.g., C1, C2, L2, Cp1, Cp2, etc., on the center frequency and other filter design parameters, a notch filter having the desired frequency response and characteristic impedance matching may be designed into (or integrated with) the main signal path, utilizing the inductor L1 that is simultaneously used for the coupler. Comparing the elements present in circuitry 305 with those present in the prior art circuitry 205 of FIG. 2, it is noted that the circuitry 305 advantageously omits one cascaded inductor (e.g., L3) from the main signal path that would otherwise be provided in a filter 220 series-coupled to a directional coupler 210. Accordingly, insertion loss for circuitry 305 is reduced compared to that for prior art circuitry 205.

It will further be appreciated that the structure of the filter built into the main signal path can generally utilize any filter techniques in which a series inductor is provided. For example, alternative filter structures need not include a parallel capacitor Ca coupled in parallel with the terminals 310a, 310b as shown in FIG. 3. Such alternative filter structures may include, e.g., providing series or shunt combinations of other inductors, capacitors in elliptic configuration, poles at infinity (e.g., Butterworth filter), etc. In view of the techniques described hereinabove, one of ordinary skill in the art may readily combine implementations of such alternative filters (e.g., which may or may not incorporate Ca) with the elements shown in FIG. 3, e.g., with the series inductor L1. Such alternative exemplary embodiments are contemplated to be within the scope of the present disclosure.

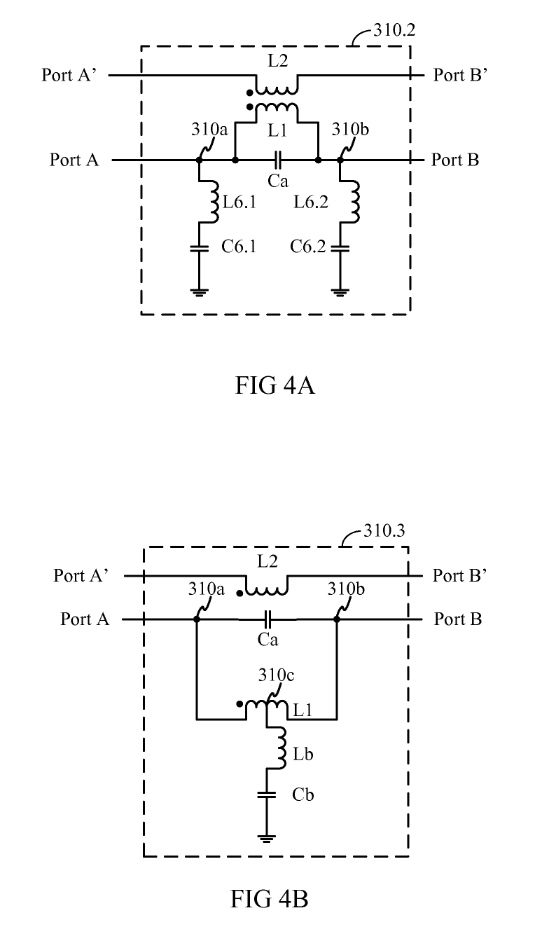

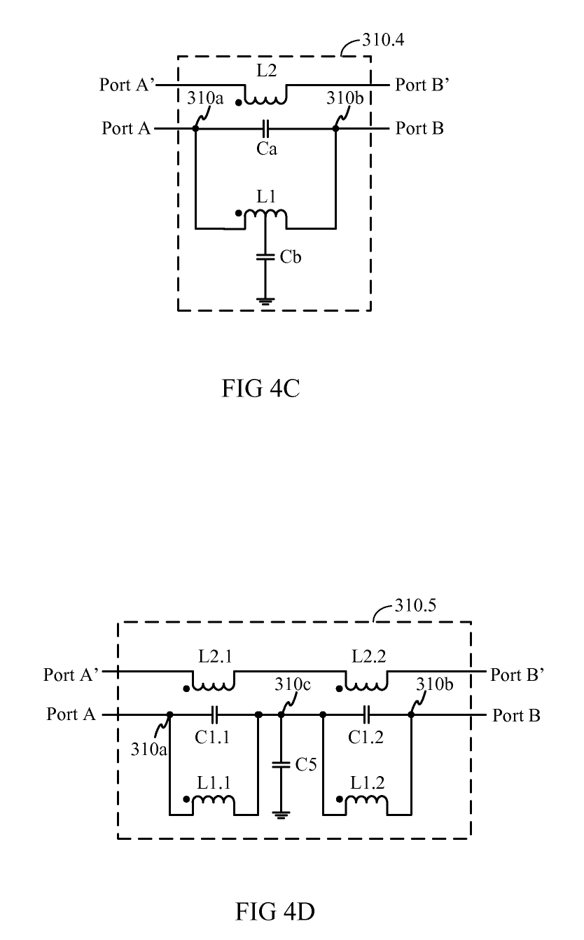

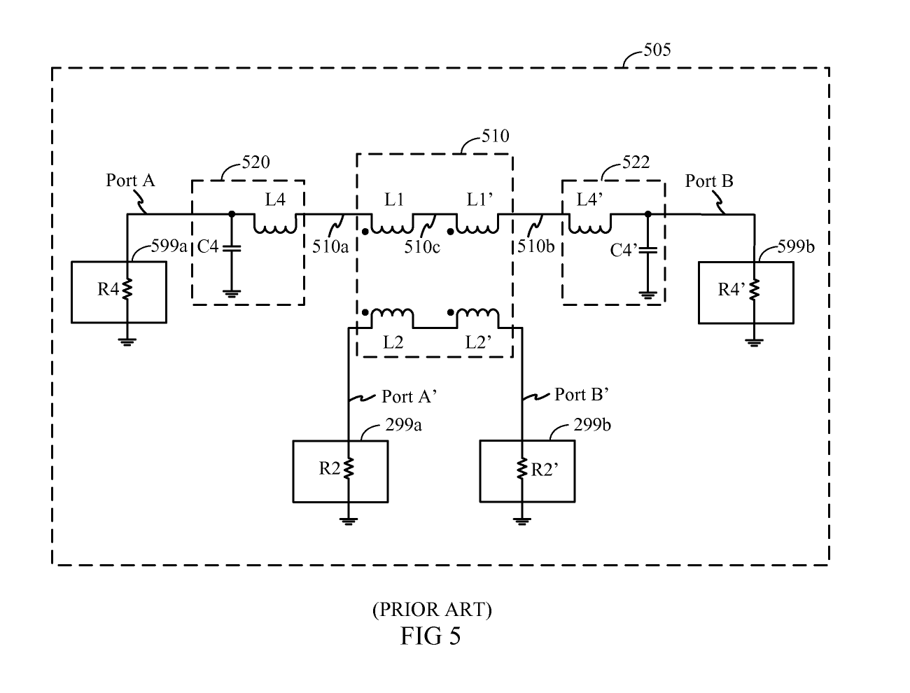

FIGS. 4A, 4B, 4C, and 4D illustrate alternative exemplary embodiments of the present invention, further showing integrated coupling, filtering, and matching functionality. Note exemplary embodiments of radio circuitry according to the present disclosure may generally substitute any of the circuitry 310.2 through 310.5 for the integrated block 310.1 shown in FIG. 3. Further note FIGS. 4A-4D are shown for illustrative purposes only, and are not meant to limit the scope of the present disclosure to any particular instances of integrated coupler, filter, and matching circuitry shown.

In FIG. 4A, circuitry 310.2 includes a first inductor L1 in the main signal path mutually coupled to a second inductor L2 in the auxiliary signal path. A parallel capacitor Ca is further coupled in parallel with the first inductor L1. Circuitry 310.2 further includes a first series L-C circuit with L6.1, C6.1 coupling terminal 310a to ground, and a second series L-C circuit with L6.2, C6.2 coupling terminal 310b to ground.

In FIG. 4B, circuitry 310.3 includes a series L-C circuit with Lb, Cb coupling a center tap of the first inductor L1 to ground. Similarly, in FIG. 4C, circuitry 310.4 includes a single capacitor Cb coupling a center tap of the first inductor L1 to ground. It will be appreciated that the “center tap” need not physically tap the inductor L1 at its precise physical center, and may generally couple to the inductor L1 at any point along its plurality of windings.

In FIG. 4D, circuitry 310.5 shows a first inductor L1 of a main signal path split into two portions L1.1 and L1.2, coupled in series with each other at a node 310c. L1.1 and L1.2 are further mutually coupled to two series-coupled portions L2.1 and L2.2, respectively, of a second inductor L2 of the auxiliary signal path. In certain exemplary embodiments, the series-coupled inductors L1.1 and L1.2 may be implemented as a single inductor L1, with the node 310c corresponding to a center tap of the first inductor L1.

FIG. 5 illustrates an alternative prior art implementation of a portion 505 of RF front-end circuitry. In FIG. 5, circuitry 505 includes a directional coupler 510 coupled in series with a first L-C matching network 520 and a second L-C matching network 522. The coupler 510 includes a first inductor in the main signal path split into two series components L1 and L1′. L1 and L1′ are further mutually coupled to respective series components L2 and L2′ of a second inductor. Matching networks 520, 522 each include a series inductor L4 or L4′ and a capacitor C4 or C4′ coupled to ground, respectively, with loads 599a, 599b further having impedances represented by resistors R4, R4′ as shown. It will be appreciated that the prior art circuitry 505 incorporates series inductors L4 and L4′ in the main signal path, in which case L4 and L4′ will undesirably contribute to the overall insertion loss of circuitry 505.

Note while even and odd mode capacitors are not explicitly shown in FIG. 5 for ease of illustration, one of ordinary skill in the art will appreciate that such capacitors may be readily incorporated in any practical implementation of the techniques disclosed herein.

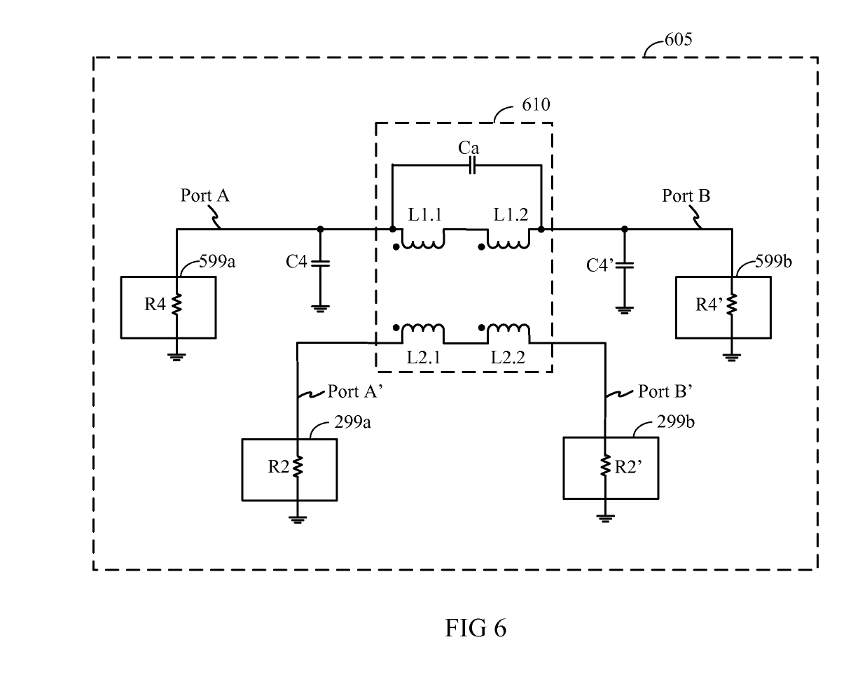

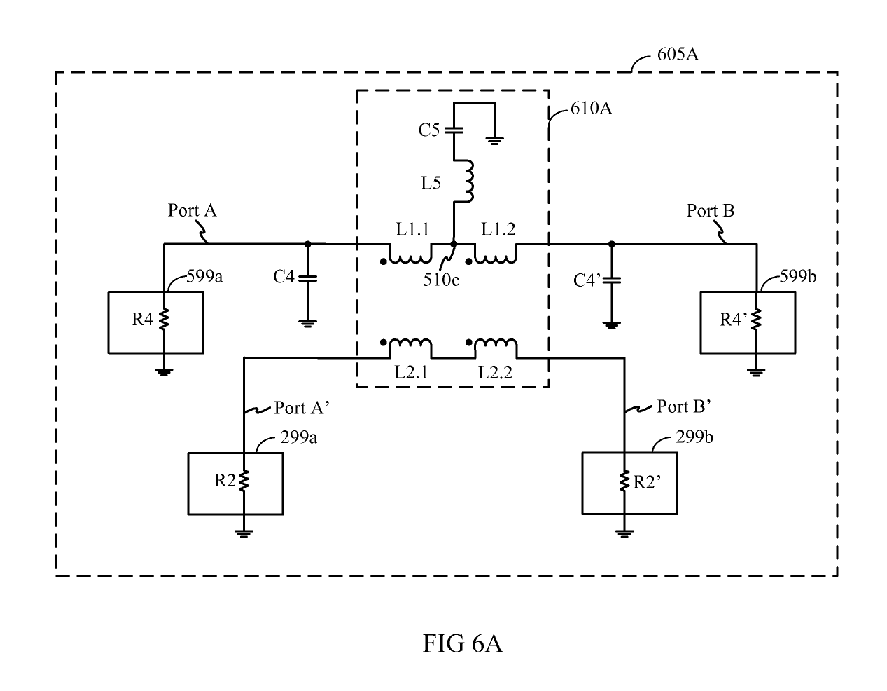

FIG. 6 illustrates an alternative exemplary embodiment 605 of RF front-end circuitry according to the present disclosure, showing certain coupler and filter components of FIG. 5 integrated into a common structure. In FIG. 6, circuitry 605 includes a directional coupler 610 having a first inductor in the main signal path split into two series components L1.1 and L1.2. L1.1 and L1.2 are mutually coupled to two series components L2.1 and L2.2 forming a second inductor. In circuitry 605, it will be noted that no additional series inductances are present between the inductors of the directional coupler 610 and Ports A and B, in contrast with, e.g., the series inductances L4 and L4′ present in the prior art circuitry 505 shown in FIG. 5. It will be appreciated that, according to the design of FIG. 6, the impedance matching functionality of input and output L-C matching networks 520 and 522 in FIG. 5 are effectively absorbed into the coupler structure 610 in FIG. 6.

In an exemplary embodiment, the values of L1.1, L1.2, L2.1, L2.2, along with the coupling factor (also denoted herein by a coupling coefficient “k”) between the inductor windings, e.g., between L1.1 and L2.1, and between L1.2 and L2.2, may be appropriately chosen to account for the absence of such additional series inductances. In this manner, the impedance matching functionality that would otherwise be afforded by the series matching networks 520, 522 of the prior art circuitry 505 of FIG. 5, or any other series concatenated inductors, may be preserved by the circuitry 605 of FIG. 6. For example, in an exemplary embodiment, the effect of inductor L4 in circuitry 505 may be effectively subsumed into a larger inductance for inductor L1.1 in circuitry 605.

In an exemplary embodiment, the values of C4 and C4′ in FIG. 6 may be chosen to appropriately account for additional parallel (e.g., parasitic) capacitances not shown in FIG. 6. For example, such additional capacitance may correspond to the parasitic capacitance Ceff1 or Ceff2, further described hereinbelow with reference to FIG. 10. In an exemplary embodiment, the values of C4, L4, C4′, and L4′ may be appropriately chosen to form a “pi-matching network” including C4, L4, C4′, and C4′, whose design principles will generally be familiar to one of ordinary skill in the art. Such alternative exemplary embodiments are contemplated to be within the scope of the present disclosure.

FIG. 6A illustrates an alternative exemplary embodiment 605A of RF front-end circuitry according to the present disclosure, showing coupler and impedance matching/filter components of FIG. 5 integrated into a common structure. In FIG. 6A, circuitry 605A includes a series L-C circuit with L5, C5 coupling a center tap 510c of the first inductor to ground.

In another aspect of the present disclosure, techniques are provided for tuning the directivity of a directional coupler with improved linearity. Directivity is a figure of merit for a directional coupler and measures how well the forward and reflected waves are kept separated from each other. In particular, achieving good directivity is often a challenging design task, and relies on very precise balancing between the inductive and capacitive components of the coupler to balance the even and odd mode velocities.

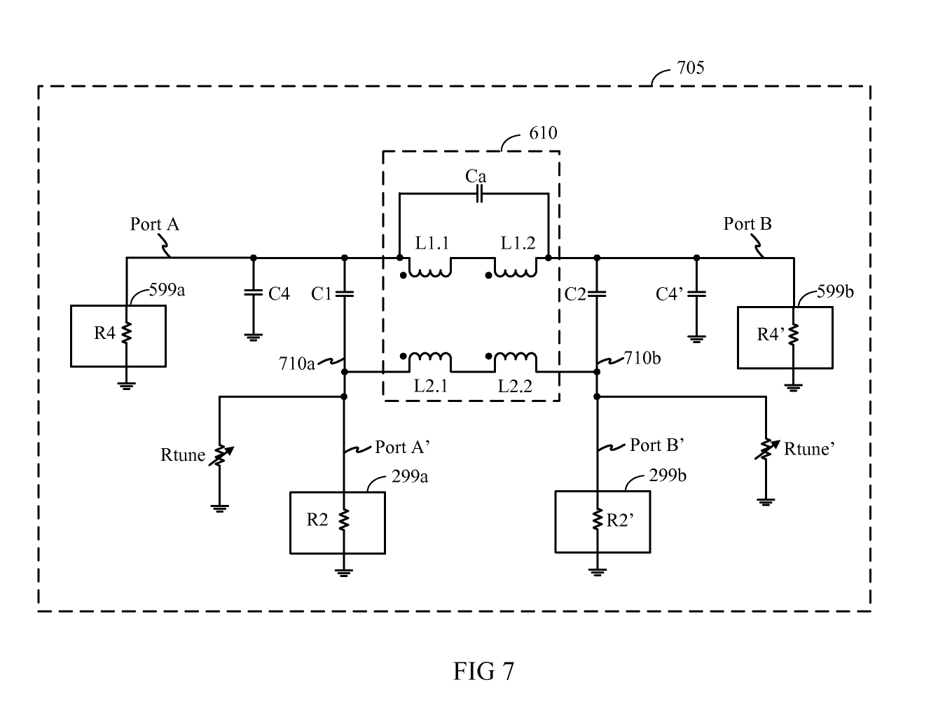

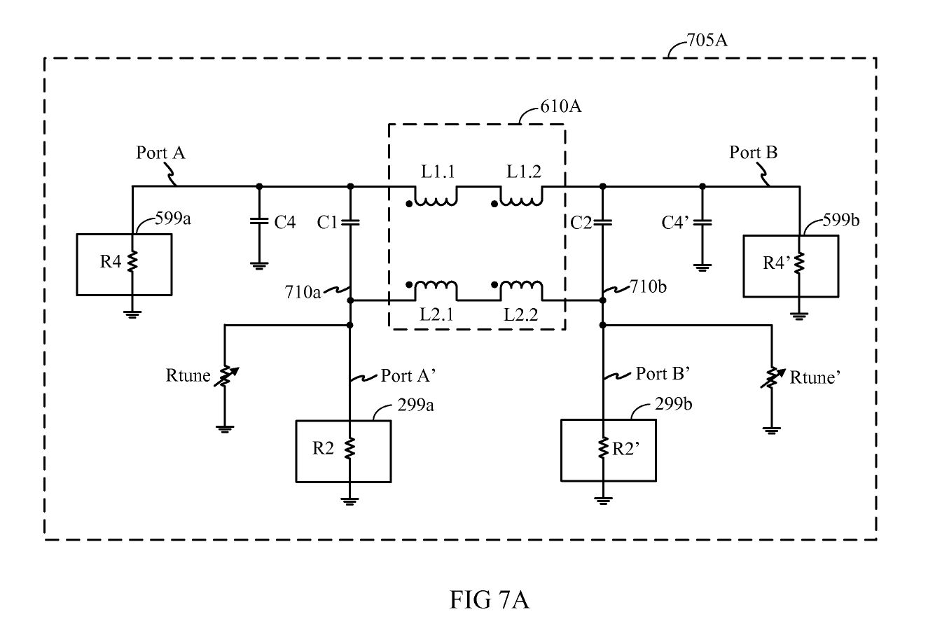

FIG. 7 illustrates an exemplary embodiment incorporating coupler directivity tuning techniques according to the present disclosure. In particular, prior art techniques for tuning the directivity of directional coupler 610 may include tuning the capacitance of the “odd-mode” capacitors C1 and C2 between the main signal path and the auxiliary signal path. A disadvantage of this approach is that non-linearity may be introduced into the main signal path, as C1 and C2 are directly coupled to the main signal path, and may thus be exposed to large-signal voltage swings. It would be desirable to provide techniques for directivity tuning causing minimal degradation to the coupler's linearity that also consumes a relatively small die area. It would also be desirable to combine the novel directivity tuning techniques with the integrated coupling and filtering techniques of the present disclosure to achieve improved performance for the RF front-end circuitry.

As further illustrated in FIG. 7, according to the present disclosure, tuning resistors Rtune and Rtune′ may be coupled as shown to the auxiliary signal path at Ports A′ and B′ to provide directivity tuning for the directional coupler. In particular, Rtune is coupled to a first terminal 710a (corresponding to Port A′) of the auxiliary signal path, while Rtune′ is coupled to a second terminal 710b (corresponding to Port B′) of the auxiliary signal path. Note Rtune and Rtune′ may correspond to, e.g., explicitly provided physical resistors dedicated to performing directivity tuning, as further described hereinbelow. In contrast, R2 and R2′ may be understood to model the effects of, e.g., input impedance, or loading, etc., from other circuit elements (not shown) coupled to Ports A′ and B′ of the coupler 610.

In an exemplary embodiment, the resistances of Rtune and Rtune′ are made configurable to allow fine tuning of the directivity of the coupler 610. It will be appreciated that as the tuning resistors Rtune and Rtune′ are directly coupled to the auxiliary signal path, as opposed to the main signal path, they are expected to have less impact on the linearity of the main signal path. This is because the signal level incident on Rtune, Rtune′ is expected to be reduced in amplitude by a mutual coupling factor (e.g., −25 dB), and thus be significantly attenuated relative to signals in the main signal path, thus leading to improved linearity.

In certain alternative exemplary embodiments, additional tuning capacitors (not shown in FIG. 7) may be placed in parallel with C1 and C2, and used in conjunction with tuning resistors Rtune, Rtune′ to fine tune the directivity. Such alternative exemplary embodiments are contemplated to be within the scope of the present disclosure.

It will be appreciated that while Rtune, Rtune′ for tuning the coupler directivity are shown in FIG. 7 in conjunction with techniques for integrating coupling and filtering (e.g., no further inductors are shown in circuitry 705 in series with the inductors of coupler 610), alternative exemplary embodiments may provide directivity tuning elements independently of the techniques for integrating coupling and filtering. For example, Rtune, Rtune′ may readily be coupled to corresponding terminals in the auxiliary signal path of the directional coupler 210 shown in FIG. 2, to advantageously provide the directivity tuning features disclosed herein to such coupler. Furthermore, FIG. 7A illustrates an alternative exemplary embodiment wherein no capacitor Ca is provided in parallel with the terminals of the inductors of circuitry 610A. Such alternative exemplary embodiments are contemplated to be within the scope of the present disclosure.

It will be appreciated that the odd-mode and even-mode capacitors associated with the coupler circuitry are not necessarily explicitly shown in the exemplary embodiments of FIGS. 6, 6A, 7, and 7A, although one of ordinary skill in the art will appreciate that such odd-mode and even-mode capacitors may readily be incorporated with the circuit techniques described herein. Such exemplary embodiments are contemplated to be within the scope of the present disclosure.

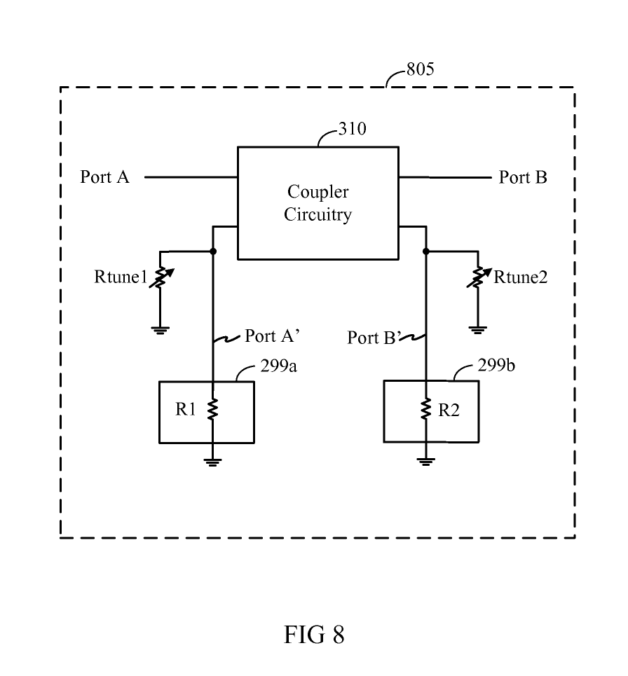

FIG. 8 illustrates an alternative exemplary embodiment of directivity tuning techniques of the present disclosure. In FIG. 8, generalized directivity tuning resistors Rtune1 and Rtune2 are coupled to Ports A′ and B′, respectively, of the auxiliary signal path of the coupler circuitry 310. In an exemplary embodiment, Rtune1 and Rtune2 may be chosen to be higher than R1 and R2, respectively, such that the parallel combinations of Rtune1 with R1 and Rtune2 with R2 nominally match each port impedance (e.g., impedance of Port A′ and impedance of Port B′) to the characteristic impedance of the circuitry coupled thereto. In an exemplary embodiment, Rtune1 and Rtune2 may optimally be tuned in tandem to achieve directivity tuning in the auxiliary path. For example, when Rtune1 is increased then Rtune2 may also be increased, and when Rtune1 is decreased then Rtune 2 may also be decreased, and vice versa. In a further exemplary embodiment, Rtune1 and Rtune2 may further be adjusted in equal increments, e.g., when Rtune1 is increased by an incremental step value, then Rtune2 is also increased by the same incremental step value, etc.

In an exemplary embodiment, adjusting Rtune1 and Rtune2 to be higher may advantageously compensate for C1 and C2 (e.g., the odd-mode capacitors) being too low in value. For example, if C1 and C2 are sub-optimally low by 20%, then proportionally increasing Rtune1 and Rtune2 by 20% may restore the desired directivity to the coupler. In a similar manner, adjusting Rtune1 and Rtune2 to be lower may advantageously compensate for C1 and C2 being too high in value. Such exemplary embodiments are contemplated to be within the scope of the present disclosure.

It will be appreciated that coupler circuitry 310 may generally adopt any of the integrated coupling and filtering techniques earlier described hereinabove, e.g., with reference to FIGS. 3, 4A-4D, etc. Such alternative exemplary embodiments are contemplated to be within the scope of the present disclosure.

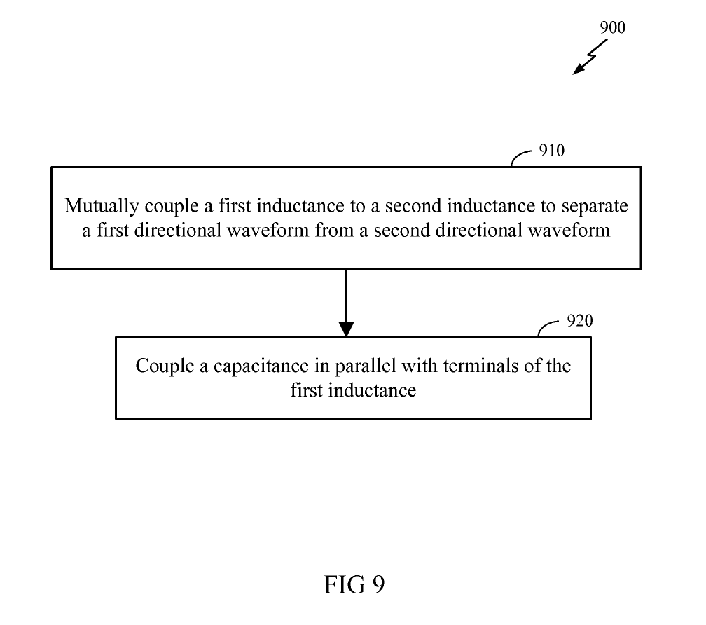

FIG. 9 illustrates an exemplary embodiment of a method according to the present disclosure. Note FIG. 9 is shown for illustrative purposes only, and is not meant to limit the scope of the present disclosure to any particular methods shown.

In FIG. 9, at block 910, a first inductance is mutually coupled to a second inductance to separate a first directional waveform from a second directional waveform.

At block 920, a capacitance is coupled in parallel with terminals of the first inductance.

FIG. 10 illustrates an alternative exemplary embodiment 1000 illustrating certain techniques of the present disclosure as applied to an analog switch module (ASM). Note FIG. 10 is shown for illustrative purposes only, and is not meant to limit the scope of the present disclosure.

In FIG. 10, a primary antenna 148.1 is coupled to circuitry 1005.1, and secondary antenna 148.2 is coupled to circuitry 1005.2. Note the two antennas 148.1, 148.2 may correspond to, e.g., multiple antennas provided for spatial diversity in a wireless apparatus. In alternative exemplary embodiments (not shown), more than two antennas may readily be provided and coupled to corresponding RF front-end circuitry, consistent with the techniques disclosed herein. Such alternative exemplary embodiments are contemplated to be within the scope of the present disclosure.

In an exemplary embodiment, circuitry 1005.1 and/or circuitry 1005.2 may be implemented using the same techniques described hereinabove with reference to, e.g., circuitry 305 of FIG. 3. For example, circuitry 1005.1 may further include coupler circuitry 310 implemented using any of the techniques described hereinabove, e.g., with reference to FIGS. 3 and 4A-4D. Circuitry 1005.1 and/or circuitry 1005.2 may further (or alternatively) be implemented using the same techniques described hereinabove with reference to, e.g., circuitry 605, 605A, 705, and/or circuitry 705A, described hereinabove with reference to FIGS. 6, 6A, 7, and 7A, respectively. Note capacitances Ceff1 and Ceff2 are coupled to terminals of circuitry 1005.1 and 1005.2, respectively, and may each correspond to, e.g., parasitic capacitance such as associated with Cp2 coupled to Port B/C in FIG. 3.

Further shown in FIG. 10 is a cross-switching block 1020 including switches S1-S9 selectively coupling terminals of circuitry 1005.1 and circuitry 1005.2 with further processing circuitry of the exemplary embodiment 1000. In particular, per cross-switching techniques known to one of ordinary skill in the art, the switches S1-S6 may selectively series-couple a primary signal path 1051, an alternative path 1052, and a secondary signal path 1053 either to, e.g., the combination of circuitry 1005.1 and antenna 148.1, or to the combination of circuitry 1005.2 and antenna 148.2. In an exemplary embodiment, alternative path 1052 may be coupled to circuitry for processing signals according to a wireless standard different from those processed by the primary and secondary signal paths 1051, 1053. For example, alternative path 1052 may be configured to process GSM signals.

In FIG. 10, an illustrative implementation of a switching block 1010 is shown coupled to the main signal path 1051. In an exemplary embodiment, switching block 1010 may correspond to a single-pole N-throw (SPNT) switching block. It will be appreciated that the switching block 1010 is shown for illustrative purposes only, and is not meant to limit the scope of the present disclosure.

In particular, switching block 1010 further selectively couples the primary signal path 1051 to, e.g., one of a plurality of instances of signal processing circuitry TX/RX 1, TX/RX 2, etc., up to TX/RX N. In an exemplary embodiment, each of the instances of TX/RX circuitry may be associated with, e.g., a particular frequency band, such that the switching block 1010 allows signal processing circuitry for N bands to share the primary signal path 1051 using, e.g., time-division multiplexing. While the switching block 1010 associated with the primary signal path 1051 is illustratively shown, it will be appreciated that alternative exemplary embodiments may readily incorporate further switching blocks (not shown) coupled to alternative path 1052 and secondary path 1053. Such alternative exemplary embodiments are contemplated to be within the scope of the present disclosure.

Note in certain exemplary embodiments, switches S7-S9 may be configured to selectively ground certain portions of the circuitry, e.g., those portions not in active use during an operational mode.

While FIG. 10 shows an illustrative application of the techniques of the present disclosure to an analog switch module, it will be appreciated that the techniques disclosed herein need not be implemented using such a switch module. For example, the RF front end circuitry techniques disclosed with reference to FIGS. 3, 4A-4D, and 6-7 may generally be implemented in single-band radios as well as multi-band radios. Such alternative exemplary embodiments are contemplated to be within the scope of the present disclosure.

In this specification and in the claims, it will be understood that when an element is referred to as being “connected to” or “coupled to” another element, it can be directly connected or coupled to the other element or intervening elements may be present. In contrast, when an element is referred to as being “directly connected to” or “directly coupled to” another element, there are no intervening elements present. Furthermore, when an element is referred to as being “electrically” or “conductively coupled” to another element, it denotes that a path of low resistance is present between such elements, while when an element is referred to as being simply “coupled” to another element, there may or may not be a path of low resistance between such elements. When an element is referred to as being “mutually coupled” to another element, it denotes that such elements may be magnetically coupled to each other.

Those of skill in the art would understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Those of skill in the art would further appreciate that the various illustrative logical blocks, modules, circuits, and algorithm steps described in connection with the exemplary aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the exemplary aspects of the invention.

The various illustrative logical blocks, modules, and circuits described in connection with the exemplary aspects disclosed herein may be implemented or performed with a general purpose processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The steps of a method or algorithm described in connection with the exemplary aspects disclosed herein may be embodied directly in hardware, in a software module executed by a processor, or in a combination of the two. A software module may reside in Random Access Memory (RAM), flash memory, Read Only Memory (ROM), Electrically Programmable ROM (EPROM), Electrically Erasable Programmable ROM (EEPROM), registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

In one or more exemplary aspects, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-Ray disc where disks usually reproduce data magnetically, while discs reproduce data optically with lasers. Combinations of the above should also be included within the scope of computer-readable media.

The previous description of the disclosed exemplary aspects is provided to enable any person skilled in the art to make or use the invention. Various modifications to these exemplary aspects will be readily apparent to those skilled in the art, and the generic principles defined herein may be applied to other exemplary aspects without departing from the spirit or scope of the invention. Thus, the present disclosure is not intended to be limited to the exemplary aspects shown herein but is to be accorded the widest scope consistent with the principles and novel features disclosed herein.

1. An apparatus comprising:
a directional coupler comprising a first inductance mutually coupled to a second inductance; and
a capacitor coupled in parallel with terminals of the first inductance.

2. The apparatus of claim 1, the terminals of the first inductance corresponding to the end terminals of the first inductance.

3. The apparatus of claim 1, further comprising a series-LC circuit coupling each terminal of the first inductance to ground.

4. The apparatus of claim 1, further comprising a series-LC circuit coupling a center tap of the first inductance to ground.

5. The apparatus of claim 1, further comprising a capacitor coupling a center tap of the first inductance to ground.

6. The apparatus of claim 1, further comprising:
a series first inductance;
a series second inductance mutually coupled to the series first inductance; and
a second capacitor coupled in parallel with end terminals of the series first inductance;
a grounding capacitor coupling a terminal between the first inductance and the series first inductance with ground.

7. The apparatus of claim 1, further comprising resistors coupling terminals of the second inductance to ground, wherein at least one of the resistors has tunable resistance to optimize the directivity of the apparatus.

8. The apparatus of claim 7, wherein both resistors have tunable resistance.

9. The apparatus of claim 7, the second inductance comprising a first series inductance coupled with a second series inductance.

10. The apparatus of claim 1, further comprising:
a transmit signal path having an output coupled to a first terminal of the first inductance; and
an antenna coupled to a second terminal of the first inductance.

11. An apparatus comprising:
a directional coupler comprising a first inductance mutually coupled to a second inductance, the first inductance comprising first and second inductors coupled in series; and
a series L-C circuit coupling a node of the first inductance to ground;
wherein the directional coupler directly conductively couples a power amplifier output to an antenna.

12. The apparatus of claim 11, further comprising first and second tuning resistors coupling terminals of the second inductance to ground, wherein at least one of the first and second tuning resistors has a configurable resistance.

13. A method comprising:
mutually coupling a first inductance to a second inductance to separate a first directional waveform from a second directional waveform;
coupling a capacitance in parallel with terminals of the first inductance.

14. The method of claim 13, further comprising:
coupling each terminal of the first inductance to ground using a series L-C circuit.

15. The method of claim 13, further comprising:
coupling a center tap of the first inductance to ground.

16. The method of claim 13, further comprising:
coupling terminals of the second inductance to ground via tuning resistors, wherein at least one of the tuning resistors has a configurable resistance.

17. The method of claim 16, wherein both of the tuning resistors has a configurable resistance.
